(19) United States
(12) Patent Application Publication
(10) Pub. No.: US 2026/0007081 A1
(43) Pub. Date: Jan. 1, 2026

(54) PROJECTED PHASE CHANGE MEMORY DEVICE WITH LOW-CONDUCTANCE NON-VOLATILE STATES

(71) Applicant: International Business Machines Corporation, Armonk, NY (US)

(72) Inventors: Ghazi Sarwat Syed, Kilchberg (CH); Vara Sudananda Prasad Jonnalagadda, Wallisellen (CH); Timothy Mathew Philip, Albany, NY (US); Abu Sebastian, Adliswil (CH)

(21) Appl. No.: 18/755,007

(22) Filed: Jun. 26, 2024

(51) Int. Cl. H10N 70/20; H10B 63/10; H10N 70/00

(52) U.S. Cl. CPC H10N 70/231; H10B 63/10; H10N 70/063; H10N 70/826; H10N 70/8413

(57) ABSTRACT

A PCM memory structure having extended projection liner material portion to reduce conductance value in a SET state and increase power efficiency. The projection liner material layer includes bottom and vertically extending liner sidewall portions. A phase change material (PCM) layer positioned above the projection liner material layer also has vertically extended PCM sidewall portions that are shorter than the vertically extending liner sidewall portions, thereby increasing the length of the liner relative to a length of the PCM layer. In a RESET state, current flow bypasses an amorphous volume to reduce the device non-idealities yet leverage the in-plane resistivity of the liner to provide projection in the RESET states and to lower the conductance in the SET states of the device thereby reducing current and power dissipation and power consumption will be lowered when in a SET state.

### BACKGROUND

The present application relates to a memory structure, and more particularly to a disc-cell phase change material (PCM) memory structure, its method of manufacture, and its operation.

Phase change materials (PCMs) have been pursued for a variety of applications such as, for example, storage class memory as well as storing weights of neural networks for artificial intelligence and in-memory computing. In typical PCMs formed as memory structures, the amount of PCM to melt and change phase can be relatively large requiring one or more high and/or long current pulses to melt the appropriate amount of PCM. This high and/or longer current duration can consume relatively large amounts of energy and use relatively large amounts of power. It is highly desirable to increase the PCM energy efficiency and decrease the amount of power consumed by the PCM memory device.

In addition, in a model training “inference” mode, an efficient device is considered to be one that has reduced non-idealities in the RESET state, as well as low conductance values in the SET and intermediate states. The latter is significantly important as it dictates the energy consumption and the scalability of the array size.

While the use of projected-type devices has allowed the reduction of the non-idealities, there still remains the problem of high-conductance values in the SET/intermediate non-volatile states.

### SUMMARY

A PCM device comprising a projected disc-cell structure and a method of fabrication.

A PCM cell having intrinsically low conductance values in the SET/intermediate states in addition to reduced PCM device non-idealities such as drift, power consumption, noise susceptibility and temperature dependence, etc.

The PCM cell includes a cell resistive liner material acting as a projection layer to mitigate device reset state non-idealities and also contribute to the reduction of set/intermediate conductance states. The PCM cell is confined to a pre-defined volume for improved programming efficacies.

In one aspect of the present disclosure, there is provided a disc-cell memory structure. The disc-cell memory structure comprises: a bottom electrode; a dielectric material layer formed above the bottom electrode; a projection liner material layer having a trench shape including a bottom portion and vertically extending liner sidewall portions formed in the dielectric material layer; a phase change material (PCM) layer positioned above the projection liner material layer, the PCM layer having vertically extended PCM sidewall portions that are shorter than the vertically extending liner sidewall portions, the length of the liner material layer thereby being increased relative to a length of the PCM layer; a further dielectric material layer formed above the PCM layer; and a top electrode (TE) positioned on top the further dielectric material layer above the PCM layer and having a first connected TE via portion landing on a top edge surface of a first vertical liner sidewall portion and a second connected TE via portion landing on a top edge surface of a second vertical liner sidewall portion.

In a further aspect, there is provided a disc-cell memory structure. The disc-cell memory structure comprises: a bottom electrode; a dielectric material layer formed above the bottom electrode; a projection liner material layer having a trench shape including a bottom portion and vertically extending liner sidewall portions formed in the dielectric material layer, and each vertically extending liner sidewall portion having an outwardly extended liner ledge portion; a phase change material (PCM) layer positioned above the projection liner material layer, the PCM layer having vertically extended PCM sidewall portions that are shorter than the vertically extending liner sidewall portions, the length of the liner material layer thereby being increased relative to a length of the PCM layer; a further dielectric material layer formed above the PCM layer; and a top electrode (TE) positioned on top the further dielectric material layer above the PCM layer and having a first connected TE via portion landing on a top surface of a first outwardly extended liner ledge portion and a second connected TE via portion landing on a top surface of a second outwardly extended liner ledge portion.

In a further embodiment, a PCM memory structure is described that includes: a bottom electrode; a dielectric material layer formed above the bottom electrode; a phase change material (PCM) layer having a trench shape including a bottom portion and vertically extending PCM sidewall portions formed in the dielectric material layer, and each vertically extending PCM sidewall portion having an outwardly extended PCM layer ledge portion; and a further dielectric material layer formed above the PCM layer; a top electrode (TE) positioned on top the further dielectric material layer above the PCM layer and having a first connected TE via portion landing on a top surface of a first outwardly extended PCM layer ledge portion and a second connected TE via portion landing on a top surface of a second outwardly extended PCM layer ledge portion.

The foregoing and other objects, features and advantages of the invention will be apparent from the following more particular descriptions of exemplary embodiments of the invention as illustrated in the accompanying drawings.

### BRIEF DESCRIPTION OF THE DRAWINGS

The various aspects, features, and embodiments of PCM memory structures; methods or techniques for making PCM memory structures; and/or the operation and function of PCM memory structures will be better understood when read in conjunction with the figures provided. It may be noted that a numbered element in the figures is typically numbered according to the figure in which the element is introduced, is typically referred to by that number throughout succeeding figures, and that like reference numbers generally represent like parts of exemplary embodiments of the invention.

Embodiments are provided in the figures for the purpose of illustrating aspects, features, and/or various embodiments of the memory structure, e.g., PCM memory structure; methods and techniques for making the memory structure, and/or the operation and function of the memory structure, but the claims should not be limited to the precise arrangement, structures, layers, features, materials, aspects, assemblies, subassemblies, functional units, embodiments, methods, processes, or devices shown.

FIG. 1A depicts a cross-sectional view of an exemplary phase change material (PCM) memory device that includes a bottom electrode layer, PCM material, and a top electrode layer forming a PCM memory device structure operative in a SET state as known in the art;

FIG. 1B shows a cross-sectional view of the exemplary phase change material (PCM) memory device of FIG. 1A, however in a RESET state of operation;

FIG. 2A shows a cross-sectional view of an exemplary PCM device structure according to an embodiment of the present disclosure where the PCM volume is confined for improved programming efficiencies and where the cell resistive liner material acts as a projection layer to mitigate device reset state non-idealities and also contribute to the reduction of set/intermediate conductance values;

FIG. 2B shows a cross-sectional view of the exemplary PCM memory device of FIG. 2A, however in a RESET state of operation;

FIG. 3A depicts a cross-sectional elevational view of an alternate embodiment of a PCM memory cell for refining and confining the PCM volume for improved programming efficiencies where the liner material acts as a projection layer and has an extended portion of length to mitigate device reset state non-idealities and contribute to the reduction of set/intermediate conductance states;

FIG. 3B shows a cross-sectional view of the exemplary phase change material (PCM) memory device of FIG. 3A, however slightly modified in that the projection liner layer is reduced relative to the projection liner length of laterally extended liner material ledge portion shown in FIG. 3A;

FIGS. 4A-4F depict method steps for generating the PCM cells in the embodiments of FIG. 3B;

FIGS. 5A-5F depict similar method steps for generating the PCM cells in the embodiment of FIG. 3A;

FIG. 6 shows a cross-sectional elevational view of a further embodiment of a PCM memory cell structure that does not include a projection liner but includes an elongated PCM cell material structure for improved programming efficiencies, e.g., for SET state operation;

FIG. 7 depicts a plot of the resistance encountered in a projected-type PCM disc cell both without and with the additional series resistor (liner) element against the amorphous material length (in nm) in an example PCM memory cell SET/RESET state simulation; and

FIGS. 8A-8C depict respective plots showing the PCM cell device RESET/SET ratio for the unprojected (without liner) case (FIG. 8A), the projected case with a liner sheet resistance (FIG. 8B) and the extended liner case with formed additional liner sheet resistance (FIG. 8C).

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. In addition, features described herein can be used in combination with other described features in each of the various possible combinations and permutations. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Unless otherwise specifically defined herein, all terms are to be given their broadest possible interpretation including meanings implied from the specification as well as meanings understood by those skilled in the art and/or as defined in dictionaries, treatises, etc. It should also be noted that, as used in the specification and the appended claims, the singular forms “a”, “an” and “the” include plural referents unless otherwise specified, and that the terms “includes”, “comprises”, and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath”, “directly under”, or “in contact with” another element, there are no intervening elements present.

The present disclosure is directed to an energy efficient phase change material (PCM) memory structure and/or device, and more particularly, to a disc-cell type PCM structure that can solve the high-conductance challenge in SET states without exposing the side walls of the phase change film during its fabrication.

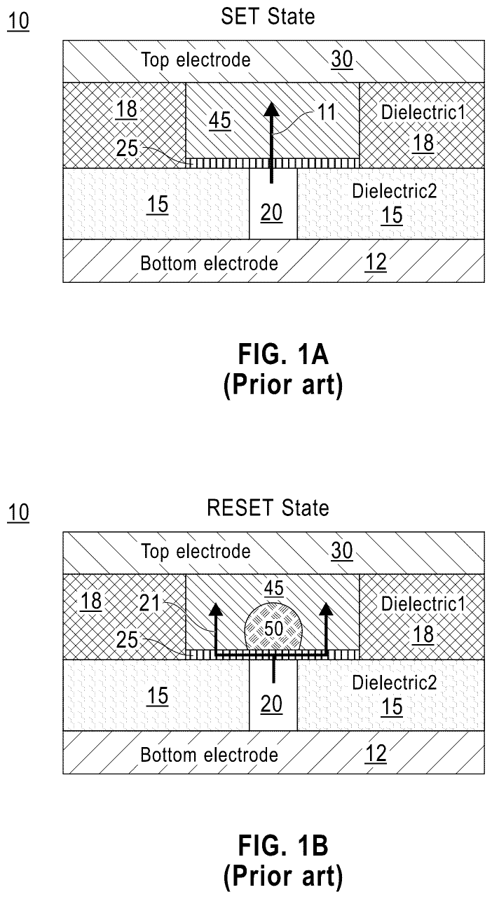

As shown in FIG. 1A there is depicted a cross-sectional view of an exemplary phase change material (PCM) memory device known in the art, and particularly a vertically integrated PCM device 10 including a phase change material structure 45 and bottom electrode 12. The device is built in a first dielectric material layer 15 formed above the bottom electrode 12 and a second dielectric material layer 18 formed above the first dielectric material layer 15. The phase change material structure 45 is embedded within the second dielectric material layer 18, and a top metal electrode 30 is formed above the dielectric material layer 18 and PCM structure 45. As shown, formed in the second dielectric material layer 15 is a projection liner 25 of metal material positioned directly below and contacting the PCM structure 45. Further formed in the dielectric material layer 15 is a heater electrode 20 having a bottom surface directly contacting the bottom electrode 12 and a top surface directly contacting the projection liner 25 beneath the PCM material structure 45. In a SET state of operation, a virtually unimpeded current 11 flows from bottom electrode to top electrode through the PCM material structure 50 and projection liner 25. That is, in the SET state of PCM cell 10, the majority of current flows through the PCM. The liner 25 contributes minimally to the resistance owing to its ultra-thinness and anisotropic resistivity values between in-plane and out-of-plane carrier transport. In the set state, when the PCM material is crystalline and electrically conductive, the device exhibits a very large Gₘₐₓ conductance value which leads to increased power consumption and temperature dependence, etc.

FIG. 1B shows a cross-sectional view of the exemplary phase change material (PCM) memory device 10 of FIG. 1A, however in a RESET state of operation. In this RESET state, the PCM material is programmed or melt quenched in a manner that a portion of the PCM structure is in an amorphous state 50 and becomes electrically insulating and/or resistive (is in an electrically insulating and/or resistive state). In FIG. 1B, the electrically insulating and/or resistive region 50 does not reach or come into contact with top electrode layer 30. As further shown in FIG. 1B, there is depicted a read current in a SET state whereby read current 21 flows through crystalline, electrically conductive PCM layer, through the projection liner 25 and around electrically insulating and/or resistive region 50. Thus, in the RESET state, the current bypasses the amorphous volume to reduce the non-idealities.

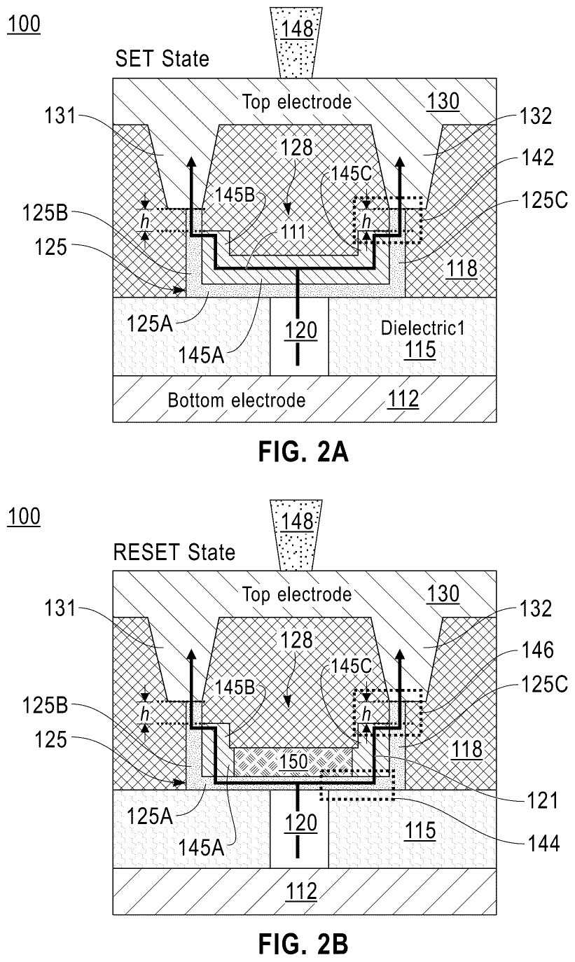

FIG. 2A shows a cross-sectional view of an exemplary PCM device structure 100 according to an embodiment of the present disclosure where the PCM volume is confined for improved programming efficiencies and where the cell resistive liner material acts as a projection layer to mitigate device reset state non-idealities and also contribute to the reduction of set/intermediate conductance states.

More particular, FIG. 2A depicts a PCM device 100 of an architecture configured to lower the conductance in the SET states of the device. As shown in FIG. 2A, the PCM device 100 is a disc-cell-type PCM cell including a bottom electrode 112, a first dielectric material layer 115 formed above the bottom electrode 112, and a second dielectric material layer 118 formed above the first dielectric material layer 115. Formed in the first dielectric material layer is a heater electrode 120 connecting the bottom electrode 112. Formed above the first dielectric material layer 115 is a projection liner 125 that includes a thin layer bottom liner portion 125A and vertical extending sidewall liner portions 125B, 125C that define a cavity 128. The top surface of the heater electrode 120 directly contacts the underside surface of thin layer bottom liner portion 125A. Formed within the cavity 128 defined by projection liner 125 is a phase change material layer including a bottom PCM material layer portion 145A and vertical extending sidewall PCM material portions 145B, 145C. Further formed above the second dielectric layer is top metal electrode 130 that includes two downward extending via portions 131, 132 with top electrode via portion 131 having an underside surface directly contacting a top surface of the projection liner portion 125B and top electrode via portion 132 having a underside surface directly contacting a top surface of the projection liner portion 125C.

In an embodiment, formed above and electrically contacting the top electrode 130 is a conductive pad 148, e.g., of a metal material, for electrical connection to other circuits or structures such as a bitline conductor (not shown). In view of FIG. 2A, in a SET state of operation, a current 111 flows from bottom electrode through the heater and the PCM material layer portion 145A and vertically extended PCM material portions 145B, 145C and through respective top portions of respective vertical extending sidewall liner portions 125B, 125C to respective via portions 131, 132 of top electrode 130. As shown in the dashed portion 142 in FIG. 2A, a small portion of the liner portion 125C that does not abut vertically extended PCM material portion 145C contributes to the lowering of the PCM device conductance in a SET state. Similarly, a small portion of the liner portion 125B that is not abutted with vertically extended PCM material portion 145B contributes to the lowering of the PCM device conductance in a SET state. In an embodiment, as shown in FIG. 2A, the PCM cell 100 is configured in a manner such that a small top portion of each vertical extending sidewall liner portion 125B, 125C indicated by a height of length “h” is not directly abutting respective vertically extended PCM material portions 145B, 145C receives current 111 when the memory cell is placed in the SET state, e.g., by conducting a current 111 from bottom electrode 112 to top electrode 130 through heater electrode 120. In an embodiment, the vertical length or height “h” having no PCM sidewall region is configurable. When programming the cell, one or more electrical pulses can be input to the PCM cell structure, and in response, enables the current flow to conduct through a small part of liner portion 125A and then through the PCM material portions 145A, 145B, 145C and additionally through the respective further liner portions of length “h” that contributes to the lowering of the SET state conductance. In an embodiment, the length of height h is controllable by etching and can be in the nanometer range, e.g., <20 nm. That is, the cell architecture depicted in FIG. 2A leverages the “in-plane” resistivity of the liner portions 125B, 125C and to lower the conductance in the SET states of the device.

FIG. 2B shows a cross-sectional view of the exemplary phase change material (PCM) memory device 100 of FIG. 2A, however in a RESET state of operation. In this RESET state, the PCM material is programmed or melt quenched in a manner that a portion of the PCM memory cell structure 145A becomes in an amorphous state 150 and becomes electrically insulating and/or resistive (i.e., is in an electrically insulating or non-conductive state). In FIG. 2B, the electrically insulating region 150 is limited in a lateral direction such that while the region 150 can encroach the respective vertically extended PCM material portions 145B, 145C, the amorphous region 150 does not extend through to cutoff current flow through the vertically extending portions 145B, 145C. As further shown in FIG. 2B, there is depicted a read current in a SET state whereby read current 121 flows through the bottom portion 125A of projection liner 125 and through each respective vertically extended PCM material portions 145B, 145C around the amorphous electrically insulating region 150 and then through the respective top portions of respective vertical extending sidewall liner portions 125B, 125C to respective via portions 131, 132 of top electrode 130. That is, as shown in the dashed portion 144 in FIG. 2B, a small portion of the liner portion 125A contributes to the projection, and as shown in the dashed portion 146 in FIG. 2B, a small portion of the liner portion 125C that is not abutted with vertically extended PCM material portion 145C contributes to the lowering of the PCM device conductance. Similarly, a small portion of the liner portion 125B that is not abutted with vertically extended PCM material portion 145B contributes to the lowering of the PCM device conductance. As shown in FIG. 2B, the PCM cell 100 is configured in a manner such that a small portion of height “h” at the top of each vertical extending sidewall liner portion 125B, 125C that is not directly abutting respective vertically extended PCM material portions 145B, 145C receives current 121 when in the SET state and contributes to the lowering of the SET state conductance. This length of the liner portion shown as height “h” having no PCM sidewall region is controllable by etching and can be in the nanometer range, e.g., <20 nm. The thickness of liner material layer 125 in general is “tunable”, e.g., to increase the resistance value for the SET state. Thus, in the RESET state, the current bypasses the amorphous volume to reduce the non-idealities yet leverage the “in-plane” resistivity of the liner to provide projection in the RESET states of the device and also to lower the conductance in the SET states of the device. The cell structure shown in FIGS. 2A, 2B thus enhance the projection efficacies due to the unique shape of amorphous volume (e.g., as compared to mushroom-cell architectures).

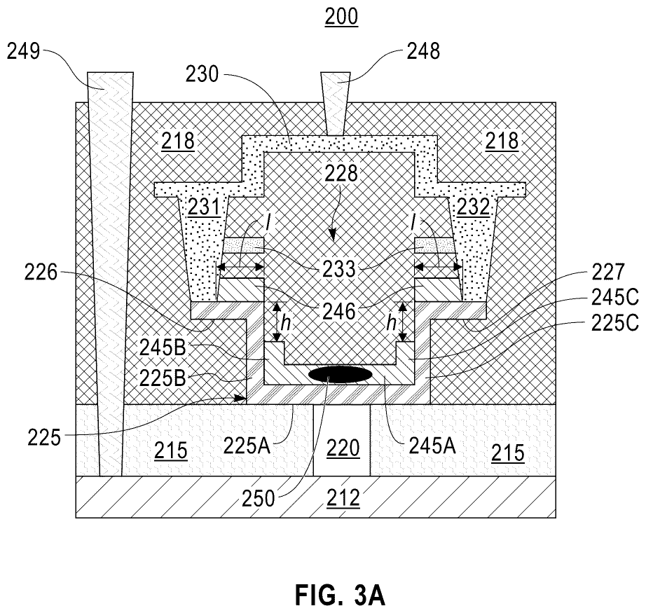

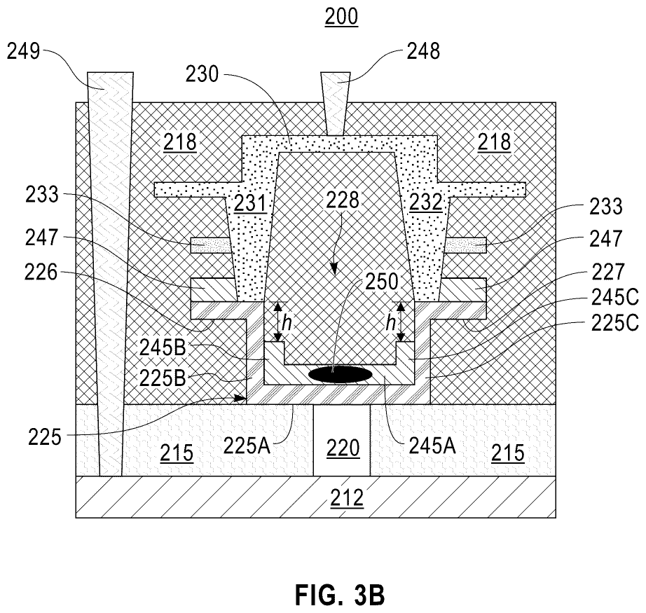

FIG. 3A depicts a cross-sectional elevational view of an alternate embodiment of a PCM memory cell 200 for refining and confining the PCM volume for improved programming efficiencies where the liner material acts as a projection layer to mitigate device reset state non-idealities and also contributes to the reduction of set/intermediate conductance states.

As shown in FIG. 3A, the PCM device 200 of the alternative embodiment is a disc-cell-type PCM cell including a bottom conductive electrode 212, a first dielectric material layer 215 formed above and directly contacting the bottom electrode 212, a second dielectric material layer 218 formed above the first dielectric material layer 215. Formed in the first dielectric material layer is a heater electrode 220 connecting the bottom electrode 212. Formed within dielectric material layer 218 above the first dielectric material layer 215 is a memory cell projection liner 225 that includes a thin layer bottom liner portion 225A and vertical extending sidewall conductive liner portions 225B, 225C that define a cell cavity 228. The thin layer bottom liner portion 225A directly contacts a top surface of the heater electrode 220. Formed within the cavity 228 defined by liner 225 is a phase change material layer including a bottom PCM material layer portion 245A and vertical extending sidewall PCM material portions 245B, 245C formed using semiconductor lithographic and material deposition processes, e.g., atomic layer deposition (ALD). Formed in PCM material layer 245A is an amorphous region 250 that is insulating or non-conductive based on a particular programming of the memory cell. As in the embodiments of FIGS. 2A, 2B, the vertical extension of the PCM material portions 245B, 245C is limited to a height of length “h” below the respective heights of respective vertical extending sidewall conductive liner portions 225B, 225C of the cell cavity. In the embodiment of PCM memory cell 200 of FIG. 3A, a top of respective vertically extended PCM material portions 245B, 245C include a respective liner material laterally extended ledge portion 226, 227 shown, in a non-limiting embodiment, as extending horizontally outward for a short length. Further formed above the second dielectric layer is top metal electrode 230 that includes two downward extending top electrode via portions 231, 232 with top electrode via portion 231 having an underside surface directly contacting a top surface at or near a distal end of the laterally extended projection liner ledge portion 226 away from the vertical projection liner sidewall portion 225B by a distance of length “l”, and with top electrode via portion 232 having an underside surface directly contacting a top surface at or near a distal end of the laterally extended projection liner ledge portion 227 away from the vertical projection liner sidewall portion 225C by a distance of length “l”. In embodiments, the distance “l” is configurable, i.e., the underside surface of top electrode via portion 231 can be formed to directly contact at any point along the top surface of the laterally extended projection liner ledge portion 226 of vertical projection liner sidewall portion 225B defining a horizontal distance of length “l” from the vertical extending liner portion 225B. Similarly, the underside surface of top electrode via portion 232 can be formed to directly contact at any point along the top surface of the laterally extended projection liner ledge portion 227 of vertical projection liner sidewall portion 225C also defining a horizontal distance of length “l” from the vertical extending liner portion 225C. Thus, in the PCM cell 200 shown in the embodiment of FIG. 3A, the extended top electrode via portion 231 can contact the projection liner surface edge such that, when operated in a SET state, any current flow through PCM cell between bottom and top electrodes will traverse a portion of vertically extended liner material sidewall portion 225B of height “h” having no PCM sidewall region (i.e., portion that abuts no PCM material) and further traverse a portion of laterally extended projection liner material ledge portion 226 of length “l” before reaching top electrode via portion 231. Similarly, the extended top electrode via portion 232 can contact the projection liner surface edge such that, when operated in a SET state, any current flow through PCM cell between bottom and top electrodes will traverse a portion of vertically extended liner material sidewall portion 225C of height “h” having no PCM sidewall region (i.e., portion that abuts no PCM material) and further traverse a portion of laterally extended projection liner material ledge portion 227 of length “l” before reaching top electrode via portion 232.

As shown in FIG. 3A, atop a portion of laterally extended liner material ledge portion 226 of length “l” is a further PCM material cell portion 246 not connecting the PCM cell portion 245B within the defined cavity 228 and similarly atop a portion of laterally extended liner material ledge portion 227 of length “l” is a further PCM material cell portion 246 not connecting the PCM cell portion 245C and thereby not contributing to the total conductance of the liner.

In an embodiment, as further shown in FIG. 3A, formed above and electrically contacting the top electrode 230 is a conductive pad 248, e.g., a via structure of metal material that extends upward beyond a top surface of top dielectric layer 218 for electrical connection to other circuits or structures such as a bitline conductor of a memory system (not shown). Similarly formed above and electrically contacting the bottom electrode 212 is a conductive pad 249, e.g., a via structure of metal material that contacts the bottom electrode 212 and extends upward from the bottom electrode thought dielectric layers 215, 218 and extends beyond a top surface of top dielectric layer 218 for electrical connection to other circuits or structures such as a wordline conductor of a memory system (not shown). Additionally, as shown in FIG. 3A, there is included a portion of a dielectric cap layer 233, e.g., of SiO₂ material or like oxide dielectric material, formed within the cavity 228 and through which the respective top electrode via portions 231, 232 are formed to extend through.

FIG. 3B shows a cross-sectional view of the exemplary phase change material (PCM) memory device 200 of FIG. 3A, however slightly modified in that the active projection liner layer portion is reduced relative to the active projection liner length of laterally extended liner material ledge portion shown in FIG. 3A. In the structure of FIG. 3B, the PCM memory device 200 is slightly modified in that conductive top electrode via 231 extends downward and contacts a respective portion of laterally extended liner material ledge portion 226 such that the length “l” is zero (l=0), i.e., the bottom surface of conductive top electrode via 231 lands at the top surface of the projection liner directly above and in alignment with sidewall liner portion 225B, and similarly, formed conductive top electrode via 232 extends downward and contacts a respective portion of laterally extended liner material ledge portion 227 such that the length “l” is zero, i.e., the bottom surface of conductive via 232 lands at the top surface of the projection liner directly above and in alignment with sidewall liner portion 225C.

Thus, in the PCM cell 200 shown in the embodiment of FIG. 3B, the extended top electrode via portion 231 can contact the liner edge such that any current flow through PCM cell between bottom and top electrodes will traverse a portion of vertically extended liner material portion 225B of height “h” having no PCM sidewall (i.e., portion that abuts no PCM material) before reaching top electrode via portion 231 and does not traverse a portion of laterally extended liner material ledge portion 226 (i.e., length “l”=0). Similarly, the extended top electrode via portion 232 can contact the liner edge such that any current flow through PCM cell between bottom and top electrodes will traverse a portion of vertically extended liner material portion 225C of height “h” having no PCM sidewall (i.e., portion that abuts no PCM material) before reaching top electrode via portion 232 and does not traverse a portion of laterally extended liner material ledge portion 227 (length “l”=0). As shown in FIG. 3B, atop a portion of laterally extended liner material ledge portion 226 not contacting the top electrode via portion 231 is a further PCM material cell portion 247 not connecting the PCM cell portion 245B within the defined cavity 228 and similarly atop a portion of laterally extended liner material ledge portion 227 is a further PCM material cell portion 247 not connecting the PCM cell portion not connecting the PCM cell portion 245C within the defined cavity 228.

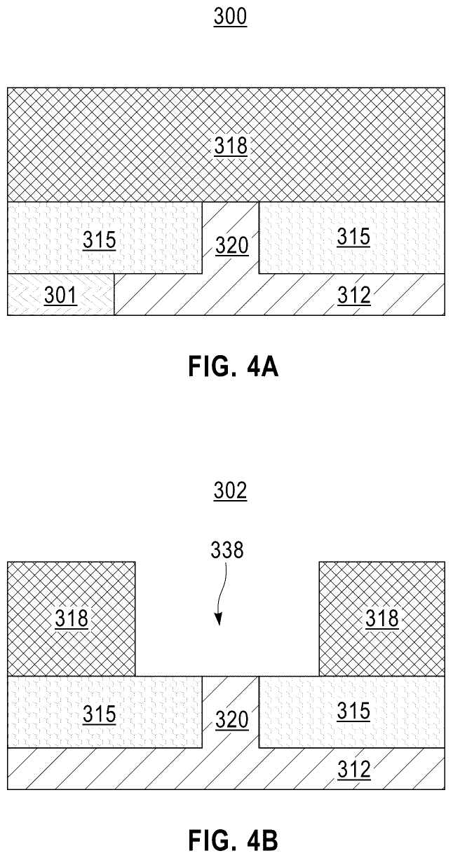

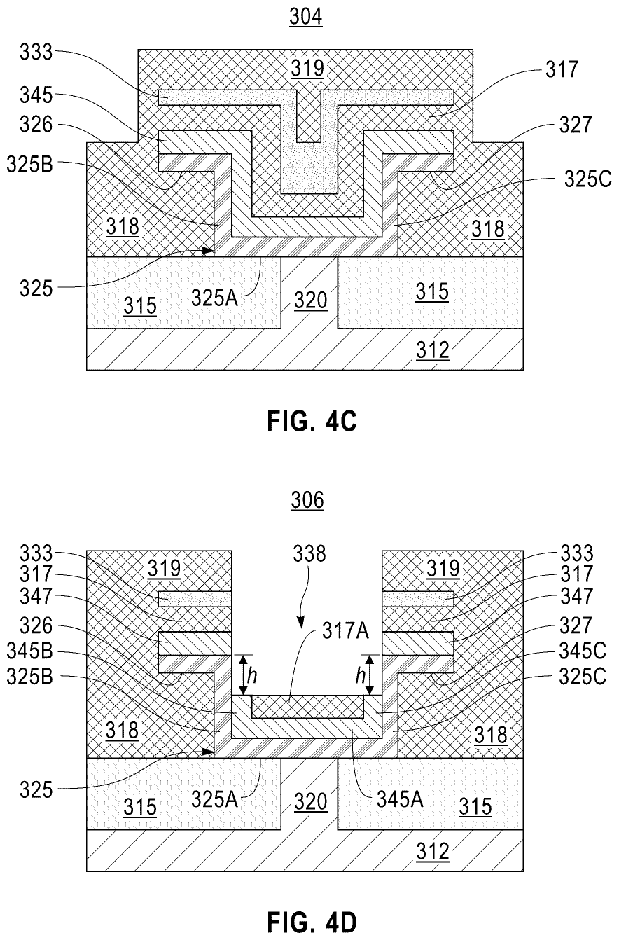

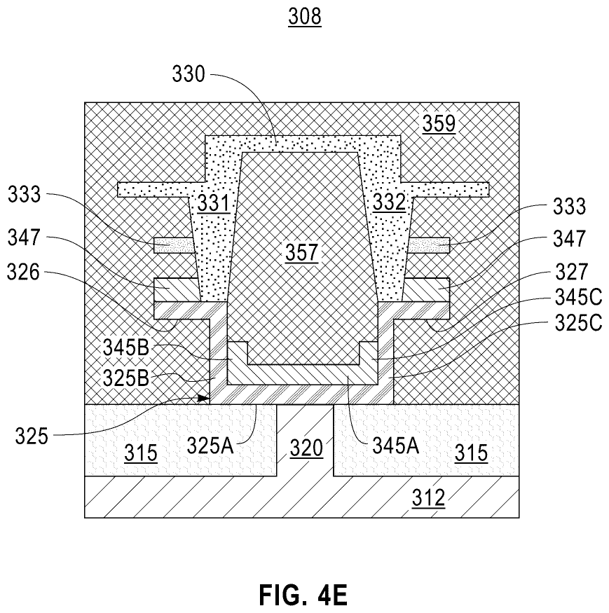

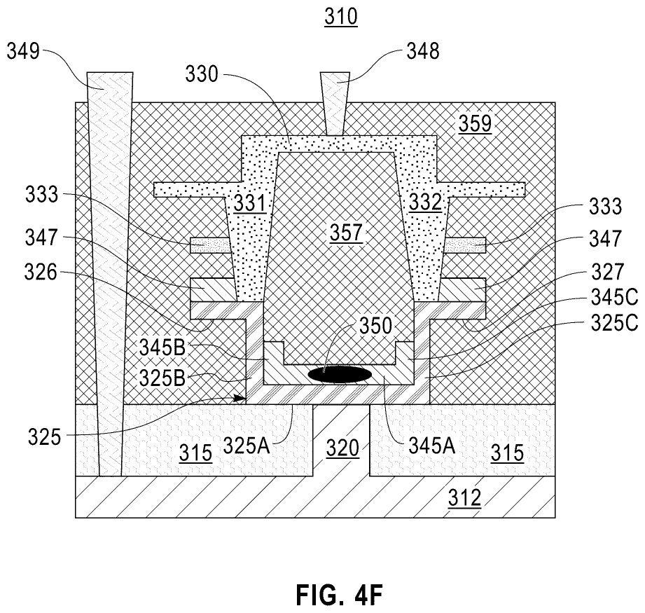

FIGS. 4A-4F depict method steps for generating the PCM cells in the embodiments of FIG. 3B. As shown in FIG. 4A, there is depicted a structure 300 resulting from initial semiconductor manufacturing steps of forming a MOSFET device or like transistor device 301 and, the forming, from bottom to top, of a bottom electrode layer 312 of a metal material, the first dielectric layer 315 (of a dielectric material such as SiO₂, Silicon Nitride (SiN), Al₂O₃), the formed heater electrode 320 within the first dielectric layer that contacts the bottom electrode 312, and the second dielectric layer 318 (of a different dielectric material such as Silicon Dioxide (SiO₂)). Illustrative examples of electrically conductive electrode materials that can be used in providing bottom electrode layer 312 include, but are not limited to: titanium nitride (TiN), tantalum nitride (TaN), ruthenium (Ru), cobalt (Co), nickel (Ni), copper (Cu), tungsten (W), tungsten nitride (WN), silver (Ag), platinum (Pt), palladium (Pd), aluminum (Al), or any suitable combination of those materials. The bottom electrode layer 312 can include a single electrically conductive electrode material or a multilayered stack of electrically conductive materials. The bottom electrode layer 312 can be formed utilizing a deposition process such as, for example, chemical vapor deposition (CVD), plasma enhanced chemical vapor deposition (PECVD), physical vapor deposition (PVD), atomic layer deposition (ALD), sputtering or plating. The bottom electrode layer 312 can have a thickness from about 10 nm to about 200 nm; although other thicknesses are contemplated and can be used in the present application (e.g., even up to 1 micron in thickness depending upon its level in CMOS). In an embodiment, the formed transistor device 301 may have a drain or source terminal (not shown) connecting to the bottom electrode 312 to provide the current used to program (e.g., SET or RESET) the formed PCM memory cell. In the manufacturing of structure 300, after depositing dielectric material layer 315, there is conducted a via etch, the deposition of heater structure 320 and a planarization, e.g., using chemical mechanical polishing (CMP) step of the heater and dielectric. The second dielectric layer 318 is then deposited to cap the first dielectric layer 315.

In an embodiment, the formed heater electrode 320 has a smaller diameter and/or width than the width of bottom electrode layer 312, and preferably smaller diameter and/or width than the width of PCM layer 345 and dimensioned to apply electrical current to melt and/or permit the PCM material cell portion to undergo a phase change. Heater electrode can be composed of an electrically conductive electrode material such as a metal-nitride (e.g., TiN, TaN) or other doped metal materials as known in the art.

FIG. 4B depicts an intermediate semiconductor memory structure 302 resulting after performing a photolithographic semiconductor process that includes an etching process (e.g., reactive-ion etch or RIE) to provide a trench opening 328 above the heater electrode 320 to expose a top surface of the heater electrode. Within trench opening 328 will be subsequently formed the PCM memory cell by PCM stack deposition steps.

FIG. 4C depicts an intermediate semiconductor memory structure 304 resulting after performing a photolithographic semiconductor process that includes depositing within the formed trench opening 328 a first projection liner material layer 325 that conforms to the bottom and sidewall surfaces of the formed trench opening and includes ledge portions 326, 327 extending outward beyond the edges of the formed opening, and an overlying layer 345 of PCM material, and a further overlying dielectric material cap layer 317 above the PCM material layer 345. In embodiments, the projection liner 325 is formed of an electrically resistive non-switching material that preferably shunts amorphous state and reduces resistance drift. In an embodiment, the liner material may consist of TiN, TaN, Carbon, etc. and deposited using ALD/CVD process to form bottom liner portion 325A, sidewall liner portions 325B, 325C and liner material ledge portions 326, 327. In an embodiment the projection liner layer 325 has a thickness that preferably ranges from about 2 nm to about 10 nm thick, e.g., about 3 nm, although other lesser or greater values for liner thickness are contemplated to “tune”, e.g., increase the resistance.

The deposited PCM material layer 345 includes any material that undergoes a phase change from crystalline to amorphous or vice versa when energy is applied thereto whereby the electrical properties of the material also change. In embodiments, the phase change material (PCM) that can be used for PCM layer 345 includes a chalcogenide that contains an element from Group 16 (i.e., a chalcogen) of the Periodic Table of Elements. Examples of chalcogens that can be used as the phase change material include, but are not limited to, a GeSbTe alloy (GST), a SbTe alloy, or an InSe alloy. Other materials such as, for example, Cr₂Ge₂Te₆ (CrGeT), can also be used as the phase change material so long as this other material can retain separate amorphous and crystalline states. Alternatively, other suitable materials for the phase change material include Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver-indium-antimony-tellurium) alloys, Ge—In—Sb—Te alloys, Ge—Sb alloys, Sb—Te alloys, Si—Sb alloys, and combinations thereof. In some embodiments, the phase change material can further include nitrogen, carbon, and/or oxygen. In some embodiments, the phase change material can be doped with dielectric materials including but not limited to aluminum oxide (Al₂O₃), silicon oxide (SiO₂), tantalum oxide (Ta₂O₅), hafnium oxide (HfO₂), zirconium oxide (ZrO₂), cerium oxide (CeO₂), silicon nitride (SiN), silicon oxynitride (SiON), etc. . . . PCM layer 345 can be formed utilizing a deposition process such as, for example, CVD, PECVD, PVD, or ALD. The PCM material layer 345 can be deposited to a thickness ranging from about 2 nm to 15 nm, e.g., about 3 nm, and takes the shape of the trench.

Using semiconductor manufacturing processes, there is performed a further processing step to spin coat HSQ (Hydrogen silsesquioxane) to form a resist layer that hardens into an oxide (e.g., the SiO₂) layer 333 for protecting the PCM material and to facilitating subsequent lithographic patterning steps. The structure 304 of FIG. 4C results after a further ion milling and/or RIE step of the HSQ cap layer 333 at a middle portion overlying the opening and the deposition of a further top dielectric cap layer 319 atop the formed SiO₂ layer 333.

FIG. 4D depicts an intermediate semiconductor memory structure 306 resulting after performing semiconductor processes including the lithographic patterning of a resist (not shown) that exposes the sidewall of the PCM layer 345 and an etching to form a trench opening 338 in the structure 304 of FIG. 4C to form the final PCM material cell structure having PCM bottom portion 345A and sidewall portions 345B, 345C extending along respective sidewalls 325B, 325C within trench opening 328 and to further expose sidewall liner portions of the liner layer 325 by selective etching to remove PCM material at the upper portion of liner sidewalls 325B, 325C without damaging the respective projection liner sidewalls 325B, 325C. The RIE (or ion milling) etch process performed can be an etch of the structure 304 of FIG. 4C selective to the PCM and liner material layers with the etch rate of the PCM material greater than the etch rate of the projection liner to prevent physical etching of the liner. After selective etching, the resulting structure 306 includes a trench opening 338 formed by removing portions of the top dielectric cap material layer 319 and underlying dielectric material layers 317, 333 and portions of PCM material layer 345 abutting the projection liner sidewalls 325B, 325C. The etch performed is selective to the PCM material layer 345 and liner material and several etches can be performed and timed to remove the portions of PCM material layer 345 that results in forming the resulting PCM cell structure including the bottom PCM material layer 345A and vertically extended portions 345B, 345C that extend along a portion of respective liner material sidewalls 325B, 325C and further results in the removal of the PCM material layer portions to form each vertically extended sidewall PCM portions 345B, 345C to define the respective heights “h” of liner material having no PCM sidewall material. As shown in FIG. 4D, remaining on liner ledge portions 326, 327 are PCM material portions 347 which are isolated and do not connect with vertical extended PCM portions 345B, 345C. Further as shown in FIG. 4D, there remains a dielectric material portion 317A above the bottom PCM layer 345A between and having a common planar top surface with the top surfaces of vertical extended PCM material portions 345B, 345C.

FIG. 4E depicts an intermediate semiconductor memory structure 308 resulting after performing a deposition step to deposit cap dielectric material 357, e.g., an oxide material, to fill in the remaining trench opening 338 formed in the structure 306 of FIG. 4D. Then, there is performed lithographic processes to form a resist mask (not shown) at the surface of the structure used to form top electrode structure including respective mask openings aligned anywhere over the respective ledge portions 326, 327 of the liner material layer 325. Then a RIE etch process is performed to etch the structure to define the top electrode features including forming of connecting top electrode vias through the mask openings where the vias are etched through remaining stack of layers 319, 333, 317 and PCM material layer 347 and land at each respective liner ledge portion 326, 327. After etching the two vias that extend from top electrode to the surface of a liner ledge portion 326, 327, there is further performed top electrode metal material deposition to deposit top electrode metal material in each of the formed vias to form the top electrode (TE) via portions 331, 332 extending downward to electrically connect with a surface of the respective liner ledge portions 326, 327 and depositing to form in the same step, the top electrode structure 330 connecting the vias 331, 332 as shown in FIG. 4E. The top electrode metal material 330 may be further etched and a further cap dielectric material may be deposited above the top electrode 330 to form a cap dielectric layer 359 and which dielectric material encapsulates the whole structure as shown in FIG. 4E. The top electrode masking, etching and material deposition processes performed in FIG. 4E result in the formation of the top electrodes at any distance “l” along a top surface of the ledges 326, 327 as desired to tailor the length of the projection liner ledge portion acting as the projection layer to mitigate device reset state non-idealities and also contributes to reduction of set/intermediate conductance states. In FIG. 4E, the length l=0.

FIG. 4F depicts a semiconductor memory structure 310 resulting after performing via etching steps to form the respective via openings to be filled with conductor metal material used to form respective pads for connecting respective bottom electrode 312 and top electrode 330 to further devices or circuits (not shown) at subsequent back-end-of-line (BEOL) processes. Then a via metal material deposition step is performed to deposit conductive metal material to form the bottom electrode pad 349 and top electrode pad 348 that both extend to the top surface of the resulting structure 310, e.g., for connection to respective wordline or bitline conductors of a memory system if there is no selector. In the structure 310 of FIG. 4F, since the largest contact resistance is with the heater 320, the amorphous phase will evolve as a disk 350 in the PCM material layer 345A abutting the heater electrode.

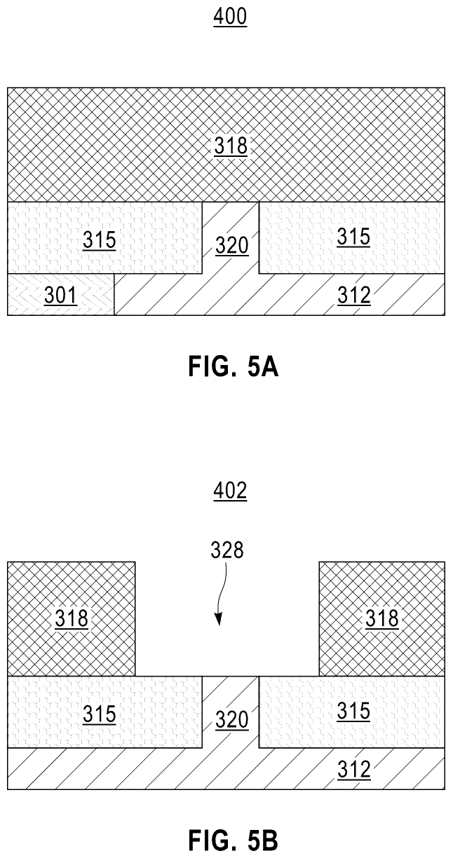

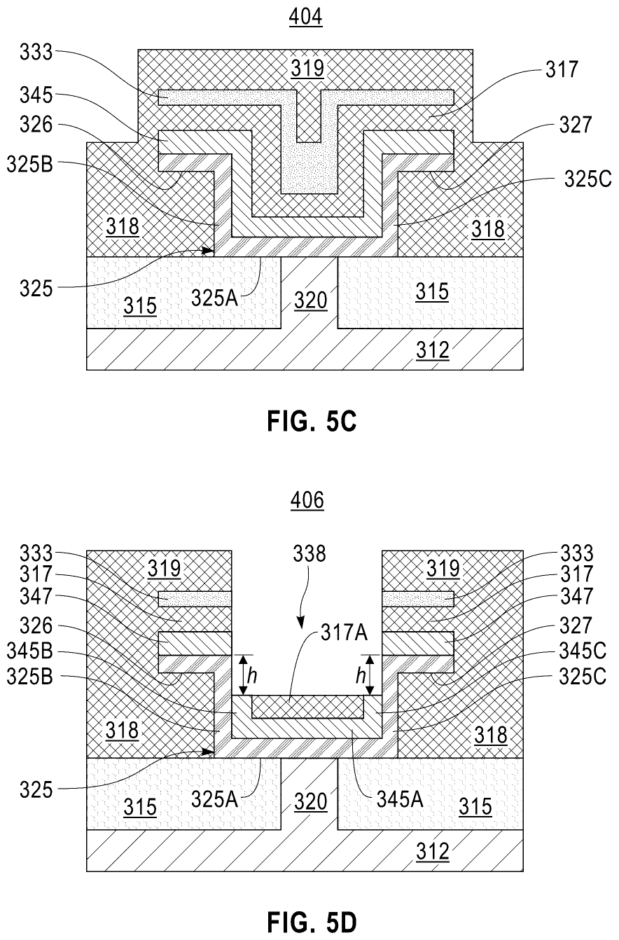

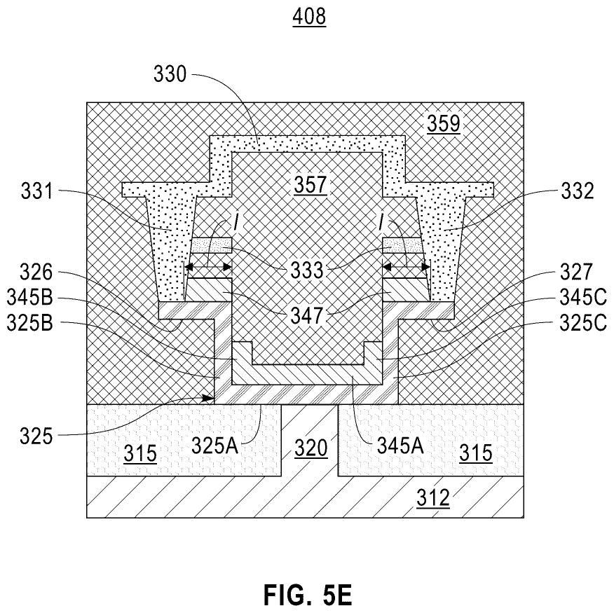

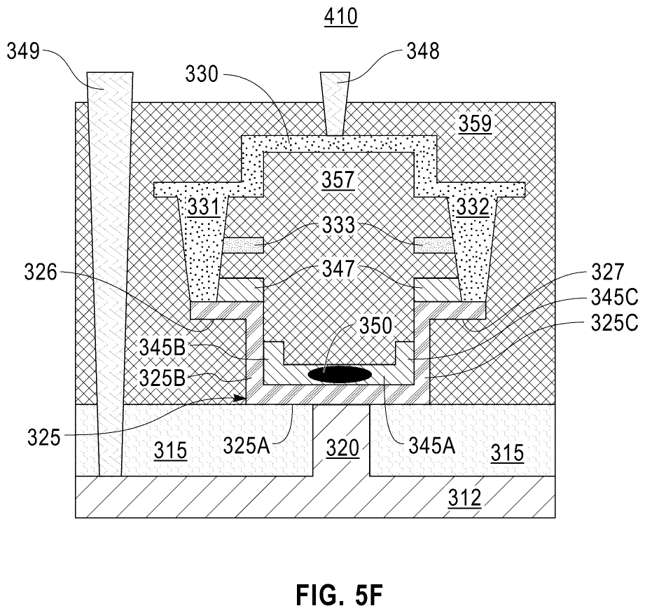

FIGS. 5A-5F depict similar method steps for generating the PCM cells in the embodiment of FIG. 3A. As shown in FIG. 5A, there is depicted an intermediate semiconductor memory structure 400 resulting from initial semiconductor manufacturing steps of forming a MOSFET device or like transistor device 301 and, the forming, from bottom to top, of the bottom electrode layer 312 of a metal material, the first dielectric layer 315, the second dielectric layer 318, and the formed heater electrode 320 within the first dielectric layer that contacts the bottom electrode 312 and extends through the first dielectric material layer 315. The transistor device 301 may have a drain or source terminal (not shown) connecting to the bottom electrode 312 to provide the current used to program (e.g., SET or RESET) the formed PCM memory cell. In the manufacturing of structure 300, after depositing dielectric material layer 315, there is conducted a via etch, the deposition of heater structure 320 and a planarization, e.g., using chemical mechanical polishing (CMP) step of the heater and dielectric. The second dielectric layer 318 is then deposited to cap the first dielectric layer 315.

FIG. 5B depicts an intermediate semiconductor memory structure 402 resulting after performing a photolithographic semiconductor process that includes an RIE etching process to provide a trench opening 328 above the heater to expose a top surface of the heater 320. Within trench opening 328 will be subsequently formed the PCM memory cell by PCM stack deposition steps.

FIG. 5C depicts an intermediate semiconductor memory structure 404 resulting after performing a photolithographic semiconductor process that includes depositing within the formed trench opening 328 the projection liner material layer 325 that conforms to the bottom and sidewall surfaces of the formed opening and includes ledge portions 326, 327 extending outward beyond the edges of the formed opening, and an overlying layer 345 of PCM material, and a further overlying dielectric material cap layer 317 above the PCM material layer 345. Using semiconductor manufacturing processes, there is performed a further spin coating processing step to form an HSQ (Hydrogen silsesquioxane) resist layer that hardens and transforms into the SiO₂ layer 333. The structure 404 of FIG. 5C results after a further ion milling and/or RIE step of the HSQ cap layer 333 at a middle portion overlying the opening and the deposition of a further top dielectric cap layer 319 atop the formed SiO₂ layer 333. In an embodiment, the liner material may consist of non-insulating materials such as metal oxides, metal nitrides, metal silicon nitrides and doped Carbon, etc. and deposited using ALD/CVD process to form bottom liner portion 325A, sidewall liner portions 325B, 325C and liner material ledge portions 326, 327 of a thickness of about 3 nm, or lesser or greater thicknesses. The overlying PCM material layer 345 can be deposited to a thickness of about 3 nm and takes the shape of the liner and trench.

FIG. 5D depicts an intermediate semiconductor memory structure 406 resulting after performing semiconductor processes including the lithographic patterning of a resist (not shown) that exposes the sidewall of the PCM layer 345 and an etching to form a trench opening 338 in the structure 404 of FIG. 5C to form the final PCM material cell structure having PCM bottom portion 345A and sidewall portions 345B, 345C extending along respective sidewalls 325B, 325C within trench opening 328 and to further expose sidewall liner portions of the liner layer 325 by etching to remove PCM material at the upper portion of liner sidewalls 325B, 325C without damaging the respective projection liner sidewalls 325B, 325C. The RIE or ion milling etch process performed can be an etch of the structure 404 of FIG. 5C selective to the PCM and liner material layers with the etch rate of the PCM material greater than the etch rate of the projection liner to prevent physical etching of the liner. Thus, after selective etching, the resulting structure 406 includes an opening 338 formed by removing portions of the dielectric material layers 317, 333 and dielectric cap material layer 319 and portions of PCM material layer 345 abutting the projection liner sidewalls 325B, 325C. The etch performed is selective to the PCM material layer 345 and liner material and several etches can be performed and timed to remove the portions of PCM material layer 345 that results in forming the resulting PCM cell structure including the bottom PCM material layer 345A and vertically extended portions 345B, 345C that extend along a portion of respective liner material sidewalls 325B, 325C and further results in the removal of the PCM material layer sidewall portions above the vertically extended portions 345B, 345C to define the respective heights “h” of liner material having no PCM sidewall material. As shown in FIG. 5D, remaining on ledge portions 326, 327 are PCM material portions 347 which are isolated and do not connect with vertical extended PCM portions 345B, 345C. Further as shown in FIG. 5D, there remains a dielectric material portion 317A above the bottom PCM layer 345A between and having a common planarized top surface as the vertical extended PCM material portions 345B, 345C.

FIG. 5E depicts an intermediate semiconductor memory structure 408 resulting after performing a deposition step to deposit cap dielectric material 357 to fill in the trench opening 338 formed in the structure 406 of FIG. 5D. Then, there is performed lithographic processes to form a resist mask (not shown) at the surface of the structure used to form top electrode structure including respective mask openings aligned over the respective ledge portions 326, 327 of the liner material. Then a RIE etch process is performed to etch the structure to form the top electrode vias through the mask openings where the vias are etched through remaining stack of layers 319, 333, 317 and PCM material layer 347 and land at each respective liner ledge portion 326, 327. As shown in FIG. 5B, the TE via etching can be tailored to ensure that any memory cell current through heater electrode will traverse a further length “l” of projection liner at respective ledge portions 326, 327 before reaching top electrode vias 331, 332. After etching the two vias 331, 332, there is further performed top electrode metal material deposition to deposit top metal electrode material in each of the formed vias to form the TE via portions 331, 332 extending downward to electrically connect with a surface of the respective liner ledge portions 326, 327 and depositing to form in the same step, the top electrode structure 330 connecting the vias 331, 332 as shown in FIG. 5E. The top electrode metal material 330 may be further etched and a further cap dielectric material may be deposited above the top electrode 330 to form a cap dielectric layer 359 above the top electrode and that encapsulates the whole structure as shown in FIG. 5E. The top electrode masking, etching and material deposition processes performed in FIG. 5E result in the formation of the top electrodes at any distance “l” along a top surface of the ledges 326, 327 as desired to tailor the length of the liner ledge portion acting as the projection layer to mitigate device reset state non-idealities and also contributes to reduction of set/intermediate conductance states.

FIG. 5F depicts a structure 410 resulting after performing via etching steps to form the pad vias to be filled with conductor metal material used to form pads for connecting respective bottom electrode 312 and top electrode to further devices or circuits (not shown) in further BEOL processes. Then, a via pad metal material deposition step is performed to deposit conductive metal material to form the bottom electrode pad 349 and top electrode pad 348 that extend to the top surface of the resulting structure 310, e.g., for further connection to respective wordline or bitline conductors of a memory system if there is no selector. In the structure 410 of FIG. 5F, since the largest contact resistance is with the heater 320, the amorphous phase will evolve as a disk 350 abutting the heater electrode.

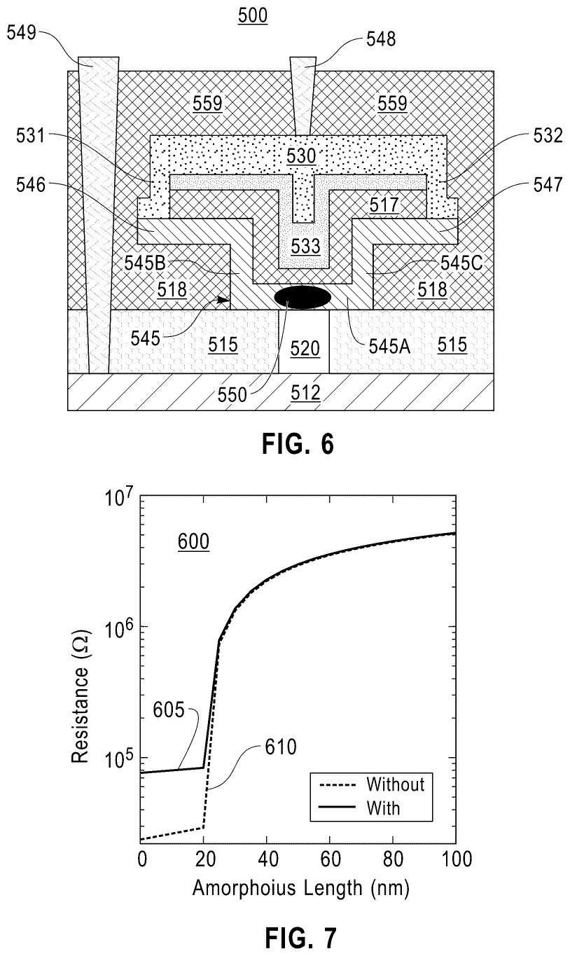

FIG. 6 shows a cross-sectional elevational view of a further embodiment of a PCM memory cell 500 structure that does not include a projection liner but includes an elongated PCM cell material structure for improved programming efficiencies by contributing to the reduction of set/intermediate conductance states (e.g., to increase resistance or decrease conductance, e.g., for SET state operation).

As shown in FIG. 6, the PCM device 600 of the alternative embodiment is a disc-cell-type PCM cell including a bottom conductive electrode 512, a first dielectric material layer 515 formed above and directly contacting the bottom electrode 512, a second dielectric material layer 518 formed above the first dielectric material layer 515. Formed in the first dielectric material layer is a heater electrode 520 connecting the bottom electrode 512. Formed within dielectric material layer 518 above the first dielectric material layer 515 and having length and width dimensions defined by a formed trench opening (not shown) is a phase change material layer 545 including a bottom PCM material layer portion 545A, vertical extending sidewall PCM material portions 545B, 545C and a top ledge portion 546 extending outward and away from PCM sidewall portion 545B and a top ledge portion 547 extending outward and away from PCM sidewall portion 545C and which can be formed using semiconductor lithographic and material deposition processes, e.g., atomic layer deposition (ALD). Capable of being formed in PCM material layer 545A is an amorphous region 550 that is insulating or non-conductive based on a particular programming of the PCM memory cell. The PCM bottom 545A, and vertically extending sidewall portions 545B, 545C define a cavity that is filled with a further dielectric cap material 517 and a further spin-coated HSQ resist layer transformed into a SiO₂ material layer 533 after development. As a result of subsequent further etching (e.g., RIE or ion milling), there is formed atop of the SiO₂ layer 533 a top metal electrode layer 530 that includes two downward extending top electrode via portions 531, 532 with top electrode metal via portion 531 having an underside surface directly contacting a top surface at or near a distal end of the laterally extended PCM layer ledge portion 546 away from the vertical PCM sidewall portion 545B by a configurable distance, and with top electrode metal via portion 532 having an underside surface directly contacting a top surface at or near a distal end of the laterally extended PCM layer ledge portion 547 away from the vertical PCM sidewall portion 545C by a configurable distance. In embodiments, the underside surface of top electrode via portion 531 can be formed to directly contact at any point along the top surface of the laterally extended PCM layer ledge portion 546 and similarly, the underside surface of top electrode via portion 532 can be formed to directly land at any point along the top surface of the laterally extended PCM layer ledge portion 547. In the embodiment depicted in FIG. 6, the SET state resistance is maximized (decreased conductance) when the top electrode metal via portion 531 lands on the top surface at the distal end of the laterally extended PCM layer ledge portion 546 and similarly when the top electrode metal via portion 532 lands on the top surface at the distal end of the laterally extended PCM layer ledge portion 547. Thus, when operated in a SET state, any current flow through PCM cell between bottom and top electrodes will traverse a longer PCM cell portion including the vertically extended PCM sidewall portions 545B, 545C and further traverse the laterally outwardly extended PCM material ledge portion 546, 547 before reaching respective top electrode via portions 531, 532. The lengths and thickness of the PCM material layer 545 is tunable in order to decrease the conductance when performing a SET operation. After TE deposition, a final top cap dielectric material layer 559 is deposited that can be the same material as the dielectric material layers 518, 517.

In an embodiment, as further shown in FIG. 6, formed above and electrically contacting the top electrode 530 is a conductive pad 548, e.g., a via structure of metal material that extends upward beyond a top surface of top dielectric layer 559 for electrical connection to other circuits or structures such as a bitline conductor of a memory system (not shown). Similarly formed above and electrically contacting the bottom electrode 512 is a conductive pad 549, e.g., a via structure of metal material that contacts the bottom electrode 512 and extends upward from the bottom electrode thought dielectric layers 515, 518 and extends beyond a top surface of top dielectric layer 518 for electrical connection to other circuits or structures such as a wordline conductor of a memory system (not shown). Additionally, as shown in FIG. 6, there is included a portion of a dielectric cap layer 533, e.g., of SiO₂ material or like oxide dielectric material, formed within the trench opening and through which the respective top electrode via portions 531, 532 are formed to extend through.

A method for manufacturing the PCM cell structure of FIG. 6 is similar to the embodiments of FIGS. 4A-4F and 5A-5F however, does not include the ALD projection liner material deposition steps. The steps can include forming the bottom electrode 512 and depositing the first dielectric material layer 515, resist patterning, etching and deposition steps to form the heater electrode 520, a surface planarizing and then depositing a cap dielectric layer 518 the heater and first dielectric layer. A next step entails forming a resist pattern and conducting an RIE via etch to etch the opening for subsequent PCM stack deposition therein. Then, using ALD processes, there is deposited a thin PCM material layer 545 (e.g., about 3 nm thick) that conforms to the surface confines of the opening and includes outward extended PCM ledge 546, 547. There is further deposited over the PCM material layer 545 a further dielectric cap material layer 517 which can be the same dielectric material as the cap dielectric layer 518. Then, further steps can include spin-coating HSQ resist layer above the second dielectric cap layer which is transformed into SiO₂ layer 533 after development and is used for protection of the PCM material during patterning and subsequent etching steps to form the top electrode and downward extending vias that land on the edge portions 546, 547 of the PCM material layer 545. Final top electrode metal or conductive material is deposited to form the top electrode above the SiO₂ layer 533 and to form the connecting top electrode via portions 531, 532 to contact the PCM material layer edge portions 546, 547 of the PCM material layer near respective distal edges thereof in order to maximize the length of PCM material the current must traverse and consequently the increased resistance encountered when current flows during SET/RESET operations. Subsequent steps may include the deposition of further cap dielectric material 559 and then making via etches to contact top and bottom electrodes to a respective wordline and bitline (not shown).

FIG. 7 depicts a plot 600 of the resistance (e.g., in Ohms) encountered in a standard PCM cell without a liner element and a projected-type PCM disc cell with the series resistor (liner) element against the amorphous material length in nm (e.g., amorphous material 250 in FIGS. 3A, 3B) in an example PCM memory cell SET/RESET state simulation. For the simulation, a PCM memory cell is formed such as shown in FIG. 3A or 3B, to have the following geometrical parameters: a Cell diameter=200 nm but can be less than or greater, e.g., 50 nm to 400 nm; a PCM layer thickness=10 nm but can be less than or greater, e.g., 1 nm to 15 nm, but can be greater; a Liner material thickness=3 nm but can be less than or greater, e.g., 15 nm; and a Trench opening height on the order of 10 nm or tens of nm but can be greater, e.g., up to 200 nm. As shown in the plot of FIG. 7, the SET resistance is increased, and additionally the RESET resistance is increased only slightly by the presence of the liner, shown as plot 605, as compared to without the presence of the liner, shown as plot 610. The resistance ratio between SET and RESET states can be tuned by optimizing the geometrical parameters. In the example shown, it is 60x.

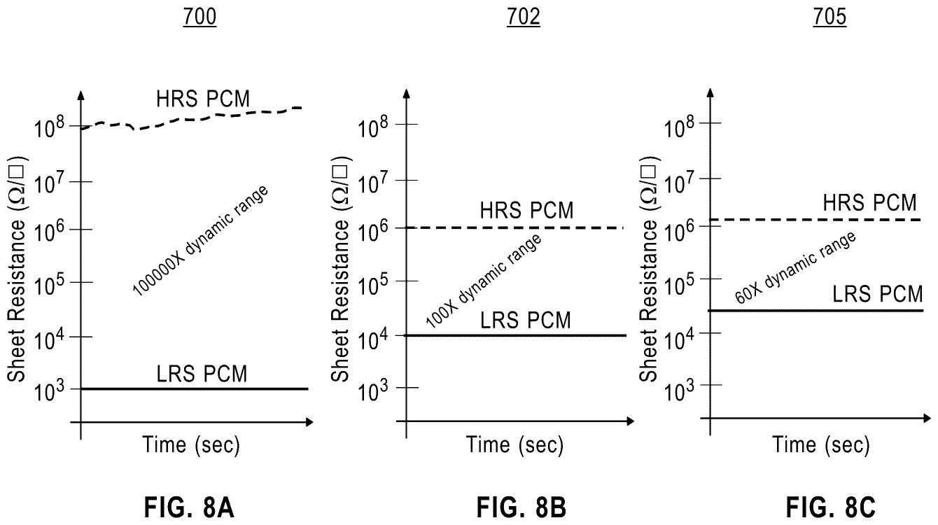

FIGS. 8A-8C depict respective plots showing the PCM cell device RESET/SET ratio for the unprojected (without liner) case 700 (FIG. 8A), the projected case 702 with a liner sheet resistance of 1 MΩ (megaohm) (FIG. 8B) and the extended liner case 705 (e.g., PCM cells of FIGS. 3A, 3B) where there is formed additional liner sheet resistance of about 1.3 MΩ (FIG. 8C). In the simulation, a method of operating a PCM memory structure includes: performing provided a RESET operation that includes providing an electrical pulse, e.g., of high current, short duration (a RESET pulse) through the bottom electrode and the heater electrode to switch the device to the high-resistance amorphous state. An electrical SET pulse (typically of lower current, longer duration) through the heater can be used to switch the PCM device back to the low-resistance crystalline state.

Each plot of FIGS. 8A-8C depict the liner sheet resistance (22/liner area, where liner area can be nm²) against time (sec). As shown in the unprojected (without liner) case of FIG. 8A, there is a 100000× dynamic range between the high resistive amorphous state (HRS PCM) vs. the low resistive crystallin state (LRS PCM). In the case of FIG. 8A, the unprojected HRS PCM suffers with larger drift but have a large dynamic range. As shown in the projected case (with liner sheet resistance of 1 M (2) case of FIG. 8B, there is a reduced (e.g., 100X) dynamic range between the high resistive amorphous state (HRS PCM) vs. the low resistive crystallin state (LRS PCM). In the case of FIG. 8B the drift issue in the HRS state is tackled by introduction of the liner, but set resistance is still low. The HRS capped by liner resistance and LRS will be added with a series resistance. As shown in the projected case (with liner sheet resistance of 1.3 MΩ) case of FIG. 8C, there is a further reduced (e.g., 60×) dynamic range between the HRS PCM state vs. the LRS PCM state. In the case of FIG. 8C, the introduction of the extended liner portions (e.g., shown in the PCM cell embodiments of FIGS. 3A, 3B) improves the set resistance with slight change in HRS resistance and can still be programmed in multiple states.

While the present application has been particularly shown and described with respect to preferred embodiments thereof, it will be understood by those skilled in the art that the foregoing and other changes in forms and details may be made without departing from the spirit and scope of the present application. The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. It is therefore intended that the present application not be limited to the exact forms and details described and illustrated, but fall within the scope of the appended claims.

What is claimed is:

1. A phase change memory structure comprising:
a bottom electrode;
a dielectric material layer formed above the bottom electrode;
a projection liner material layer having a trench shape including a bottom portion and vertically extending liner sidewall portions formed in the dielectric material layer;
a phase change material (PCM) layer conformally positioned above the projection liner material layer, the PCM layer having vertically extended PCM sidewall portions that are shorter than the vertically extending liner sidewall portions, the length of the liner material layer thereby being increased relative to a length of the PCM layer;
a further dielectric material layer formed above the PCM layer; and
a top electrode (TE) positioned on top the further dielectric material layer above the PCM layer and having a first connected TE via portion landing on a top edge surface of a first vertical liner sidewall portion and a second connected TE via portion landing on a top edge surface of a second vertical liner sidewall portion.

2. The phase change memory structure of claim 1, wherein the increased length of the projection liner material layer decreases the conductance values of the memory structure when programmed in a set state, a reset state and an intermediate states.

3. The phase change memory structure of claim 2, having a pre-defined trench volume within which the projection liner material and PCM layer is confined.

4. The phase change memory structure of claim 2, wherein the projection liner material layer is less than 5 nm and PCM layer is less than 10 nm thick.

5. The phase change memory structure of claim 2, wherein the PCM layer is electrically conductive in a crystalline state or set state and electrically resistive in an amorphous or reset state.

6. The phase change memory structure of claim 5, wherein the projection liner material layer comprises a resistive non-switching material to shunt the amorphous state and reduce a resistive drift of the PCM layer.

7. The phase change memory structure of claim 2, further comprising: a further dielectric material layer positioned on top of the top electrode and formed to surround the first connected TE via portion and the second connected TE via portion.

8. A phase change memory structure comprising:
a bottom electrode;
a dielectric material layer formed above the bottom electrode;
a projection liner material layer having a trench shape including a bottom portion and vertically extending liner sidewall portions formed in the dielectric material layer, and each vertically extending liner sidewall portion having an outwardly extended liner ledge portion;
a phase change material (PCM) layer conformally positioned above the projection liner material layer, the PCM layer having vertically extended PCM sidewall portions that are shorter than the vertically extending liner sidewall portions, the length of the liner material layer thereby being increased relative to a length of the PCM layer;
a further dielectric material layer formed above the PCM layer; and
a top electrode (TE) positioned on top the further dielectric material layer above the PCM layer and having a first connected TE via portion landing on a top surface of a first outwardly extended liner ledge portion and a second connected TE via portion landing on a top surface of a second outwardly extended liner ledge portion.

9. The phase change memory structure of claim 8, wherein the increased length of the projection liner material layer decreases the conductance values of the memory structure when programmed in a set state.

10. The phase change memory structure of claim 9, wherein each first and second outwardly extending liner sidewall portion extends from a top portion of a respective vertically extending liner sidewall portion.

11. The phase change memory structure of claim 9, wherein each first connected TE via portion lands on a top surface of a first outwardly extended liner ledge portion at or near a distal end thereof and a second connected TE via portion landing on a top surface of a second outwardly extended liner ledge portion at or near a distal end thereof.

12. The phase change memory structure of claim 11, further comprising:
a first portion of PCM material and a second portion of PCM material positioned on top of a respective first and second outwardly extending liner sidewall portion, the positioned first portion and second portion of PCM material layer being disconnected from a respective vertically extended PCM sidewall portions of said PCM layer.

13. The phase change memory structure of claim 9, having a pre-defined trench volume within which the projection liner material and PCM layer is confined.

14. The phase change memory structure of claim 9, wherein the projection liner material layer and PCM layer are less than 20 nm thick.

15. The phase change memory structure of claim 9, wherein the PCM layer is electrically conductive in a crystalline state or set state and electrically resistive in an amorphous or reset state.

16. The phase change memory structure of claim 9, wherein the projection liner material layer comprises a resistive non-switching material to shunt the amorphous state and reduce resistive drift of the PCM layer.

17. The phase change memory structure of claim 9, further comprising: a further dielectric material layer positioned on top of the top electrode and formed to surround the first connected TE via portion and the second connected TE via portion.

18. A phase change memory structure comprising:
a bottom electrode;
a dielectric material layer formed above the bottom electrode;
a phase change material (PCM) layer having a trench shape including a bottom portion and vertically extending PCM sidewall portions formed in the dielectric material layer, and each vertically extending PCM sidewall portion having an outwardly extended PCM layer ledge portion; and
a further dielectric material layer formed above the PCM layer;
a top electrode (TE) positioned on top the further dielectric material layer above the PCM layer and having a first connected TE via portion landing on a top surface of a first outwardly extended PCM layer ledge portion and a second connected TE via portion landing on a top surface of a second outwardly extended PCM layer ledge portion.

19. The phase change memory structure of claim 18, wherein a first connected TE via portion lands on a top surface of a first outwardly extended PCM layer ledge portion at or near a distal end thereof and a second connected TE via portion lands on a top surface of a second outwardly extended PCM layer ledge portion at or near a distal end thereof.

20. The phase change memory structure of claim 19, wherein the PCM layer having first outwardly extended PCM layer ledge portion and second outwardly extended PCM layer ledge portion increases a length of the PCM material layer resulting in a decrease of a conductance value of the memory structure when programmed in a set state.
